(19) United States
(12) Patent Application Publication
(10) Pub. No.: US 2025/0107011 A1
(43) Pub. Date: Mar. 27, 2025

(54) ELECTRONIC DEVICE

(71) Applicant: Samsung Display Co., LTD., Yongin-si (KR)

(72) Inventors: YOUNG DO KIM, Yongin-si (KR); SUNGHOON KIM, Yongin-si (KR); HANSUN RYOU, Yongin-si (KR); SUNGGUK AN, Yongin-si (KR); DAEYOUNG JOUNG, Yongin-si (KR); YUJIN CHOE, Yongin-si (KR)

(73) Assignee: Samsung Display Co., LTD., Yongin-si (KR)

(21) Appl. No.: 18/886,431

(22) Filed: Sep. 16, 2024

(30) Foreign Application Priority Data
Sep. 22, 2023 (KR) 10-2023-0126814

(51) Int. Cl. H05K 5/00; H05K 5/02

(52) U.S. Cl. CPC H05K 5/0086; H05K 5/0217

(57) ABSTRACT

An electronic device according to an embodiment that includes a display layer including a first non-folding display region, a second non-folding display region, and a folding display region, a support plate which may be disposed under the display layer and including a folding portion folded with respect to a folding axis, a first non-folding portion, and a second non-folding portion, an internal battery disposed under the support plate, an energy conversion layer disposed under the internal battery and electrically connected to the internal battery, a driving chip disposed under the energy conversion layer and electrically connected to the internal battery and the display layer, and a processor disposed under the driving chip and configured to drive the driving chip.

### CROSS-REFERENCE TO RELATED APPLICATIONS

This application claims priority under 35 U.S.C. § 119 from Korean Patent Application No. 10-2023-0126814 filed on Sep. 22, 2023 in the Korean Intellectual Property Office, the entire contents of which are incorporated herein by reference.

### BACKGROUND

### 1. Technical Field

The disclosure relates to an improved electronic device that autonomously generates and consumers electrical energy in a module.

### 2. Description of the Related Art

A display module includes a display layer having pixels, a driving chip (or a driving integrated circuit) which drives the pixels, and the like.

The driving chip provides the pixels with a data voltage corresponding to input image data supplied from the outside, and causes the pixels to emit light with a luminance corresponding to the data voltage.

Heat may be generated intensively at a portion of the display module in which the driving chip may be located depending on power consumption of the driving chip.

### SUMMARY

The present disclosure provides an improved electronic device that autonomously generates and consumes electrical energy in a module.

An embodiment of the disclosure provides an electronic device that may include a display layer in which a first non-folding display region, a second non-folding display region spaced apart from the first non-folding display region in a first direction, and a folding display region disposed between the first non-folding display region and the second non-folding display region may be defined, a support plate disposed under the display layer, the support plate including a folding portion folded with respect to a folding axis extending in a second direction intersecting the first direction, a first non-folding portion extending in the first direction from the folding portion, and a second non-folding portion spaced apart from the first non-folding portion by the folding portion, an internal battery disposed under the support plate, an energy conversion layer disposed under the internal battery and electrically connected to the internal battery, a driving chip disposed under the energy conversion layer and electrically connected to the internal battery and the display layer, and a processor disposed under the driving chip and configured to drive the driving chip.

In an embodiment, the internal battery may overlap at least a portion of the second non-folding portion in a plan view.

In an embodiment, the energy conversion layer may overlap at least a portion of the second non-folding portion in a plan view.

In an embodiment, the driving chip may overlap at least a portion of the second non-folding portion in a plan view.

In an embodiment, the processor may overlap at least a portion of the second non-folding portion in a plan view.

In an embodiment, the driving chip may be electrically connected to the display layer via a flexible printed circuit board, the flexible printed circuit board may include a first portion, a bending portion extending from the first portion, and a second portion extending from the bending portion, the first portion may contact the display layer, the bending portion may be bent to a rear surface of the display layer, and the driving chip may be mounted on the second portion.

In an embodiment, the energy conversion layer may convert heat generated by the processor into electrical energy.

In an embodiment, the internal battery may store the electrical energy and provide the electrical energy to the driving chip.

In an embodiment, the driving chip may be supplied with the electrical energy and may provide a driving voltage to the display layer.

In an embodiment, the energy conversion layer may include a material which operates at room temperature.

In an embodiment, a plurality of openings may be disposed in the folding portion, and the plurality of openings may be spaced apart in the first direction.

In an embodiment, the electronic device may further include a protective layer, a metal layer, a heat dissipation layer, and an insulating layer, wherein the protective layer, the metal layer, the heat dissipation layer, and the insulating layer may be disposed between the support plate and the internal battery.

In an embodiment, the protective layer may be disposed under the support plate, and the protective layer may overlap the folding portion in a plan view.

In an embodiment, the metal layer may be disposed under the protective layer, and the metal layer may not overlap at least a portion of the folding portion in a plan view.

In an embodiment, the heat dissipation layer may be disposed under the metal layer, and the heat dissipation layer may not overlap at least a portion of the folding portion in a plan view.

In an embodiment, the insulating layer may be disposed under the heat dissipation layer and disposed on the internal battery, and the insulating layer may not overlap at least a portion of the folding portion in a plan view.

In an embodiment of the disclosure, an electronic device may include a display layer, a support plate disposed under the display layer, an internal battery disposed under the support plate, an energy conversion layer disposed under the internal battery and electrically connected to the internal battery, a driving chip disposed under the energy conversion layer and electrically connected to the internal battery and the display layer, a processor disposed under the driving chip and configured to drive the driving chip, and a flexible printed circuit board electrically connecting the driving chip to the display layer, wherein the flexible printed circuit board may include a first portion, a bending portion extending from the first portion, and a second portion extending from the bending portion, the first portion may contact the display layer, the bending portion may be bent to a rear surface of the display layer, and the driving chip may be mounted on the second portion.

In an embodiment, the energy conversion layer may convert heat generated by the processor into electrical energy.

In an embodiment, the internal battery may store the electrical energy and provide the electrical energy to the driving chip.

In an embodiment, the driving chip may be supplied with the electrical energy and may provide a driving voltage to the display layer.

### BRIEF DESCRIPTION OF THE DRAWINGS

The accompanying drawings may be included to provide a further understanding of the disclosure, and may be incorporated in and constitute a part of this specification. The drawings illustrate embodiments of the disclosure and, together with the description, serve to explain principles of the disclosure. In the drawings:

FIG. 1A is a perspective view illustrating an unfolded state of an electronic device according to an embodiment of the disclosure;

FIG. 1B is a perspective view illustrating an in-folding process of the electronic device illustrated in FIG. 1A;

FIG. 1C is a plan view illustrating an in-folded state of the electronic device illustrated in FIG. 1A;

FIG. 1D is a perspective view illustrating an out-folding process according to an embodiment of the disclosure;

FIG. 2A is a perspective view illustrating an unfolded state of an electronic device according to an embodiment of the disclosure;

FIG. 2B is a perspective view illustrating a folding process of the electronic device illustrated in FIG. 2A;

FIG. 3 is a perspective view of an electronic device according to an embodiment of the disclosure;

FIG. 4 is a schematic block diagram of an electronic device according to an embodiment of the disclosure;

FIG. 5 is a schematic cross-sectional view of a display layer and a sensor layer according to an embodiment of the disclosure;

FIG. 6 is a schematic cross-sectional view of a display layer and a sensor layer according to an embodiment of the disclosure; and

FIG. 7 is a schematic cross-sectional view of the electronic device taken along line I-I′ of FIG. 1A according to an embodiment of the disclosure.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may be different directions that are not perpendicular to one another.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, embodiments of the disclosure will be described with reference to the drawings.

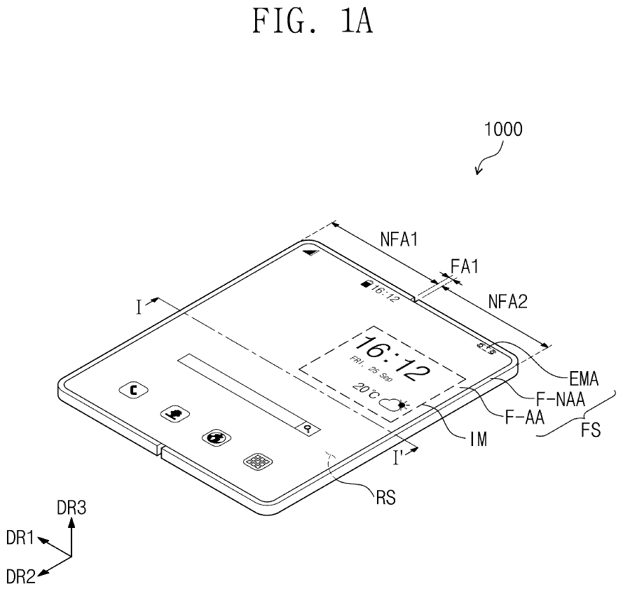

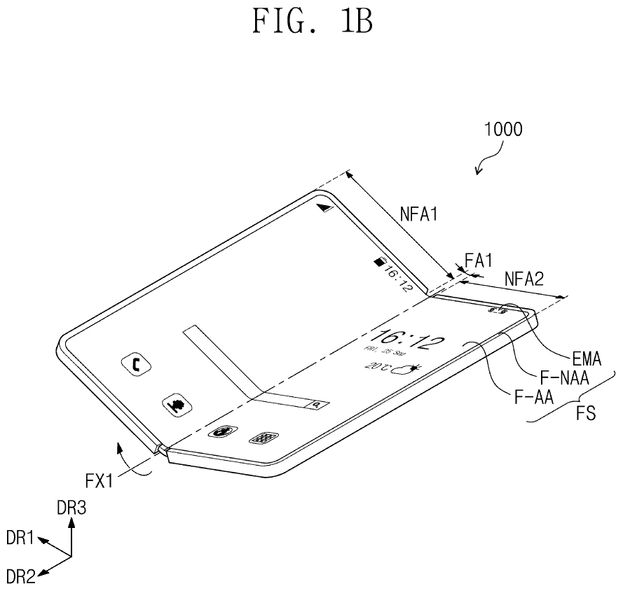

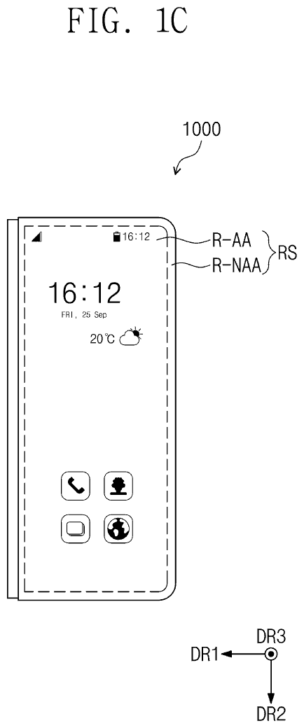

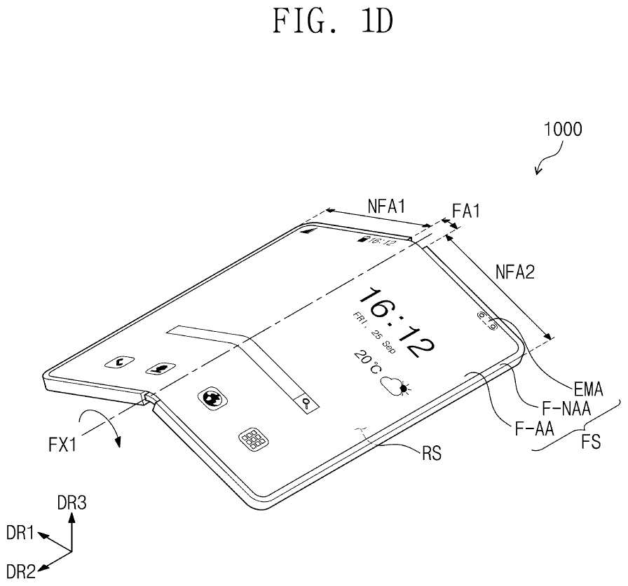

FIG. 1A is a perspective view illustrating an unfolded state of an electronic device according to an embodiment of the disclosure.

Referring to FIG. 1A, an electronic device 1000 may be activated in response to an electrical signal. For example, the electronic device 1000 may be a mobile phone, a tablet PC, a car navigation system, a game console, or a wearable device, but is not limited to thereto. In this specification, the electronic device 1000 is illustrated as a mobile phone as an example.

The electronic device 1000 may include a first display surface FS defined by a first direction DR1 and a second direction DR2 intersecting the first direction DR1. The electronic device 1000 may provide an image IM through the first display surface FS. The image IM may include a static image as well as a dynamic image. In FIG. 1A, a clock window and icons may be illustrated as an example of the image IM. In the electronic device 1000, the image IM may be displayed in a third direction DR3 on the first display surface FS which may be parallel to each of the first direction DR1 and the second direction DR2. A front surface (or a top surface) and a rear surface (or a bottom surface) of each component may be defined based on a direction in which the image IM is displayed. The front surface and the rear surface may be opposed to each other in the third direction DR3, and the normal directions of the front surface and the rear surface may be parallel to the third direction DR3.

The first display surface FS may include a first active region F-AA and a first peripheral region F-NAA. An electronic module region EMA may be included in the first active region F-AA. The electronic device 1000 may display the image IM through the first active region F-AA. The first active region F-AA may sense various forms of external input. The first peripheral region F-NAA may be adjacent to the first active region F-AA. The first peripheral region F-NAA may have a color (e.g., predetermined or selectable color). The first peripheral region F-NAA may surround the first active region F-AA. Accordingly, a shape of the first active region F-AA may be defined substantially by the first peripheral region F-NAA. However, this is illustrated as an example, and the first peripheral region F-NAA may be disposed adjacent to only a side of the first active region F-AA, or may be omitted. The electronic device 1000 according to an embodiment of the disclosure may include an active region having various shapes, and is not limited to any embodiment.

The electronic device 1000 may include a second display surface RS. The second display surface RS may be defined as a surface which may be opposed to at least a portion of the first display surface FS. The second display surface RS may be defined as a portion of a rear surface of the electronic device 1000. In an in-folded state, the second display surface RS may be viewed by a user.

Various electronic modules may be disposed in the electronic module region EMA. For example, an electronic module may include at least one of a camera, a speaker, a light detecting sensor, or a heat detecting sensor. The electronic module region EMA may sense an external subject received through the first or second display surface FS or RS or may provide an audio signal of a voice or the like to the outside through the first or second display surface FS or RS. The electronic module may include multiple components, and is not limited to any embodiment.

The electronic module region EMA may be surrounded by the first active region F-AA and the first peripheral region F-NAA. However, an embodiment of the disclosure is not limited thereto, and the electronic module region EMA may be disposed in the first active region F-AA but is not limited to any embodiment.

The electronic device 1000 may sense an external input applied from the outside. The external input may include various forms of inputs supplied from the outside of the electronic device 1000. For example, the external input may include an external input (for example, hovering) applied close to the electronic device 1000 or adjacent by a distance (e.g., predetermined or selectable distance) to the electronic device 1000 as well as a touch by a user's body part such as a hand or the like. The external input may include various forms such as physical force, pressure, heat, light, etc.

In FIG. 1A and following drawings, the first direction DR1 to the third direction DR3 may be illustrated, but the directions indicated by the first to third directions DR1, DR2, and DR3 illustrated in this specification may have a relative concept and may thus be changed to other directions. The directions indicated by the first to third directions DR1, DR2, and DR3 may be referred to as first to third directions, and thus denoted as the same reference numerals or symbols.

The electronic device 1000 may include at least one folding region FA1 and non-folding regions NFA1 and NFA2 adjacent to the folding region FA1. The non-folding regions NFA1 and NFA2 may be disposed to be spaced apart from each other by the folding region FA1.

FIG. 1B is a perspective view illustrating an in-folding process of the electronic device illustrated in FIG. 1A.

Referring to FIG. 1B, the electronic device 1000 may be folded with respect to a first folding axis FX1. The first folding axis FX1 may be an imaginary axis extending in the second direction DR2. The first folding axis FX1 may be parallel to a long-side direction of the electronic device 1000. The first folding axis FX1 may extend in the second direction DR2 on the first display surface FS.

The non-folding regions NFA1 and NFA2 may be disposed adjacent to the folding region FA1 with the folding region FA1 disposed between the non-folding regions NFA1 and NFA2. For example, a first non-folding region NFA1 may be disposed on a side of the folding region FA1 in the first direction DR1, and a second non-folding region NFA2 may be spaced apart from the first non-folding region NFA1 and disposed on another side of the folding region FA1 in the opposite direction of the first direction DR1.

The electronic device 1000 may be folded with respect to the first folding axis FX1 and deformed to an in-folded state in which a region of the first display surface FS, overlapping the first non-folding region NFA1 and another region overlapping the second non-folding region NFA2 face each other.

FIG. 1C is a plan view illustrating an in-folded state of the electronic device illustrated in FIG. 1A.

Referring to FIG. 1C, the second display surface RS may be viewed by a user when the electronic device 1000 may be in-folded. Here, the second display surface RS may include a second active region R-AA which displays an image, and a second peripheral region R-NAA which may be adjacent to the second active region R-AA. The second active region R-AA may be a region which may display an image and sense various forms of external inputs. The second peripheral region R-NAA may have a color (e.g., predetermined or selectable color). The second peripheral region R-NAA may surround the second active region R-AA. Although not illustrated, the second display surface RS may further include an electronic module region in which an electronic module having various components may be disposed, but is not limited to any embodiment.

FIG. 1D is a perspective view illustrating an out-folding process according to an embodiment of the disclosure.

Referring to FIG. 1D, the electronic device 1000 may be folded with respect to the first folding axis FX1 and deformed to an out-folded state in which a region of the second display surface RS overlapping the first non-folding region NFA1 and another region overlapping the second non-folding region NFA2 may face each other.

However, an embodiment of the disclosure is not limited thereto, and the electronic device may be folded with respect to multiple folding axes such that a portion of the first display surface FS and a portion of the second display surface RS may face each other. The number of folding axes and the number of non-folding regions corresponding thereto are not particularly limited.

The electronic device 1000 according to an embodiment of the disclosure may be configured to perform an in-folding operation or an out-folding operation repetitively, but an embodiment of the disclosure is not limited thereto. In an embodiment, the electronic device 1000 may be configured to select any one among unfolding, in-folding, and out-folding operations.

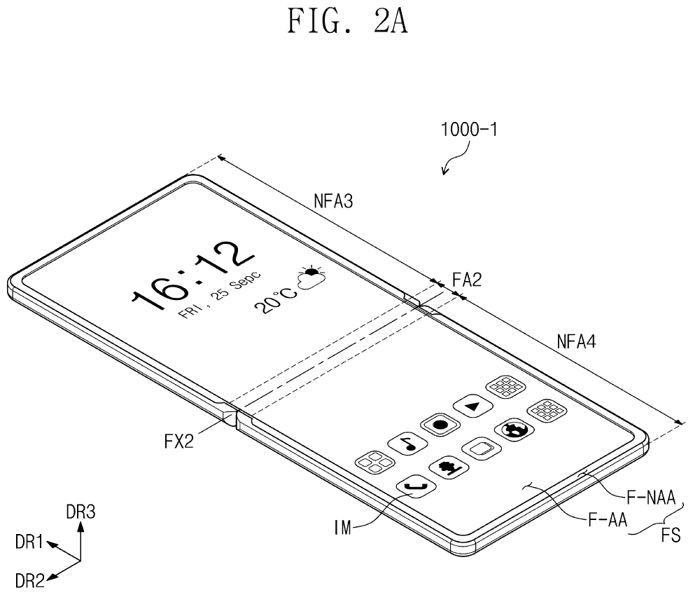

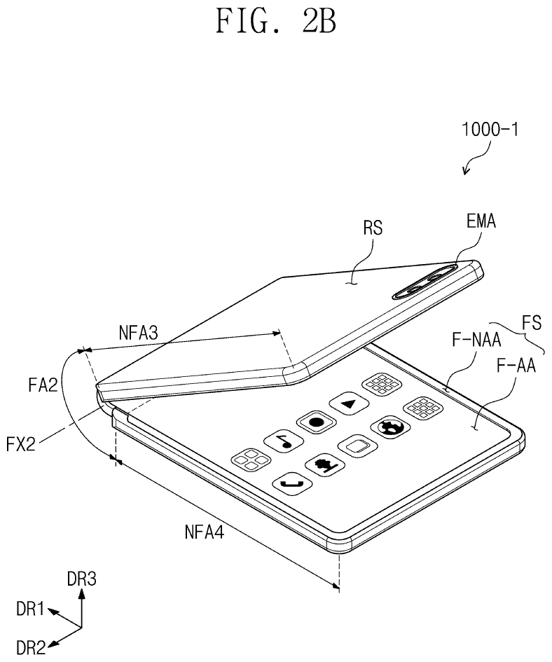

FIG. 2A is a perspective view illustrating an unfolded state of an electronic device according to an embodiment of the disclosure. FIG. 2B is a perspective view illustrating a folding process of the electronic device illustrated in FIG. 2A. In the description of FIGS. 2A and 2B, the same reference numerals or symbols may be used for the components described in FIGS. 1A to 1D, and a description thereof will be omitted.

Referring to FIGS. 2A and 2B, an electronic device 1000-1 may include a first display surface FS and a second display surface RS. The first display surface FS may include a first active region F-AA and a first peripheral region F-NAA. The second display surface RS may be defined as a surface which may be opposed to at least a portion of the first display surface FS. In an in-folded state, the second display surface RS may be viewed by a user. The second display surface RS may include an electronic module region EMA in which an electronic module having various components may be disposed. In an embodiment, an image may be provided through the second display surface RS.

The electronic device 1000-1 may include a folding region FA2 and non-folding regions NFA3 and NFA4. The electronic device 1000-1 may include multiple non-folding regions NFA3 and NFA4. The non-folding regions NFA3 and NFA4 may include a first non-folding region NFA3 and a second non-folding region NFA4 which may be spaced apart from each other by the folding region FA2.

The electronic device 1000-1 may be folded with respect to a second folding axis FX2 extending in a direction parallel to the second direction DR2. FIG. 2A illustrates that an extending direction of the second folding axis FX2 may be parallel to an extending direction of a short side of the electronic device 1000-1. However, an embodiment of the inventive concept is not limited thereto.

The folding region FA2 corresponds to a portion which may be folded with respect to the second folding axis FX2 parallel to the second direction DR2. The folding region FA2 has a curvature (e.g., predetermined or selectable curvature) and a radius of curvature (e.g., predetermined or selectable radius of curvature). In an embodiment, the electronic device 1000-1 may be in-folded so that the first non-folding region NFA3 and the second non-folding region NFA4 face each other, and the first display surface FS may not be exposed to the outside.

Unlike what is illustrated, the electronic device 1000-1 may be out-folded so that the first display surface FS may be exposed to the outside. In an embodiment, the first display surface FS may be viewed by a user in an unfolded state of the electronic device 1000-1, and the second display surface RS may be viewed by a user in an in-folded state.

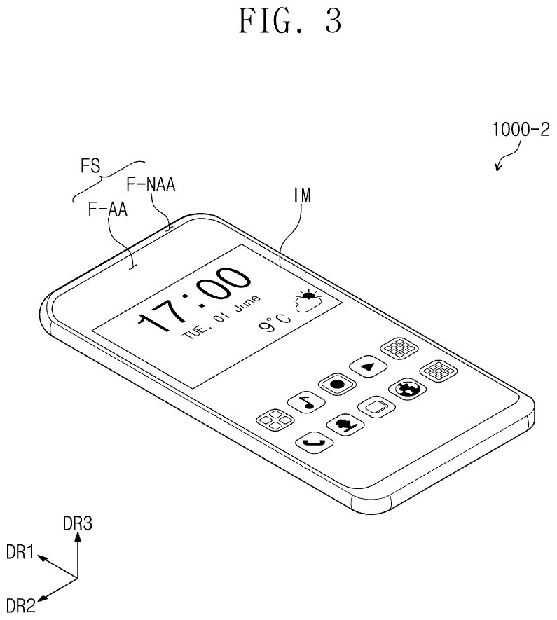

FIG. 3 is a perspective view of an electronic device according to an embodiment of the inventive concept. In the description of FIG. 3, the same reference numerals or symbols may be used for the components described in FIGS. 1A to 1D, and a description thereof will be omitted.

Referring to FIG. 3, an electronic device 1000-2 may include a first display surface FS. The first display surface FS may include a first active region F-AA and a first peripheral region F-NAA. For example, the electronic device 1000-2 may be a rigid-type electronic device.

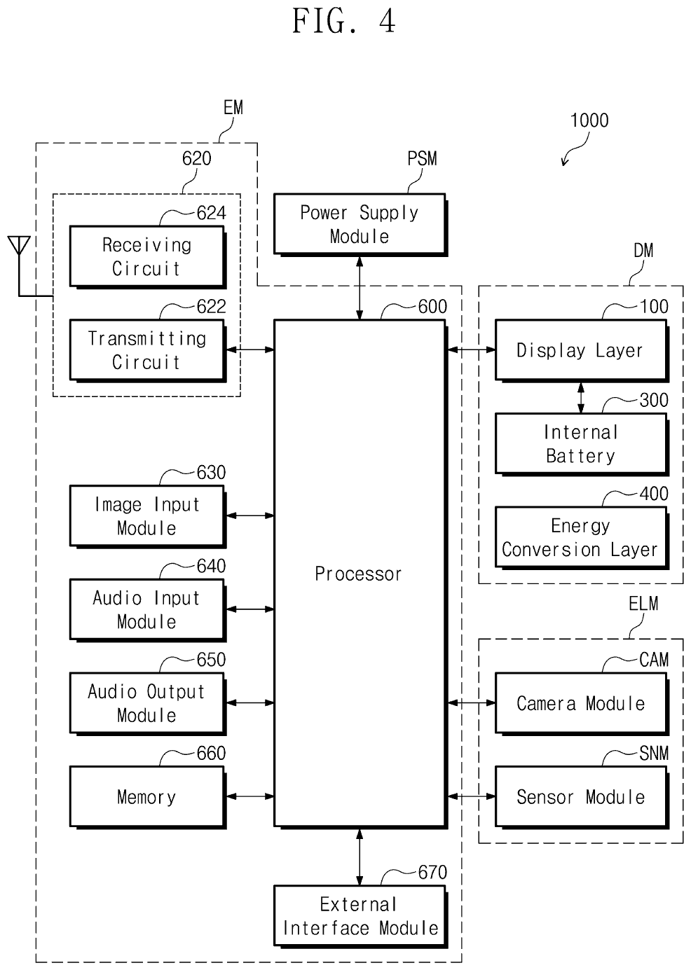

FIG. 4 is a schematic block diagram of an electronic device according to an embodiment of the inventive concept.

Referring to FIG. 4, an electronic device 1000 may include an electronic module EM, a power supply module PSM, a display module DM, and an electro-optical module ELM.

The electronic module EM may include a processor 600, a wireless communication module 620, an image input module 630, an audio input module 640, an audio output module 650, a memory 660, an external interface module 670, and the like. The modules may be mounted on a circuit board or electrically connected to the circuit board via a flexible circuit board. The electronic module EM may be electrically connected to the power supply module PSM.

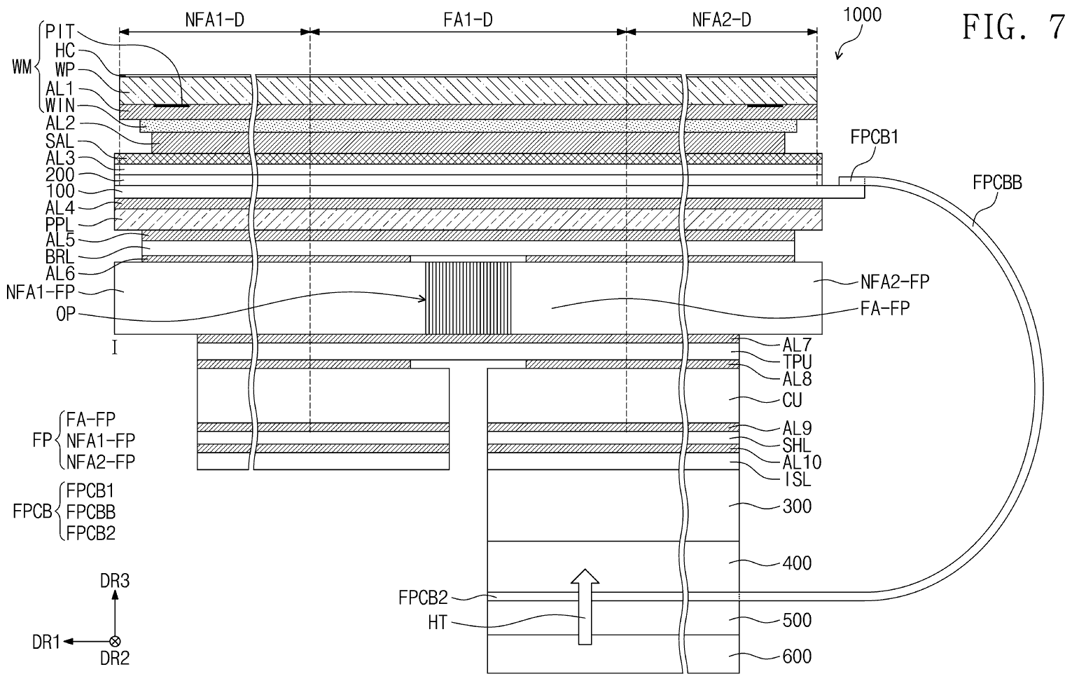

The processor 600 may control an overall operation of the electronic device 1000. For example, the processor 600 may activate or inactivate the display module DM in accordance with a user's input. The processor 600 may control the image input module 630, the audio input module 640, the audio output module 650, and the like in accordance with a user's input. The processor 600 may include at least one microprocessor. Heat HT (see FIG. 7) may be generated in case that the processor 600 is performing a control operation.

The wireless communication module 620 may transmit/receive a wireless signal to/from another terminal using Bluetooth or Wi-Fi. The wireless communication module 620 may transmit/receive an audio signal using a general communication line. The wireless communication module 620 may include a transmitting circuit 622 which modulates and transmits a signal to be transmitted, and a receiving circuit 624 which demodulates a received signal.

The image input module 630 may process an image signal and convert the image signal into image data displayable in the display module DM. The audio input module 640 may receive an external audio signal which may be input by a microphone in a recording mode, a voice recognition mode, or the like and may convert the external audio signal into electrical audio data. The audio output module 650 may convert and output, to the outside, audio data which may be received from the wireless communication module 620 or which may be stored in the memory 660.

The external interface module 670 may serve as an interface electrically connected to an external charger, a wired/wireless data port, a card socket (for example, a memory card, a SIM/UIM card), etc.

The power supply module PSM may supply power required for an overall operation of the electronic device 1000. The power supply module PSM may include a typical battery device. For example, the power supply module PSM may include a rigid-type lithium-ion battery.

The display module DM may include a display layer 100, an internal battery 300, and an energy conversion layer 400. The display layer 100 may generate an image.

The internal battery 300 may be a component which supplies a driving chip 500 (see FIG. 7) with power to drive the display layer 100.

The energy conversion layer 400 may convert the heat HT generated in the processor 600 or the heat (for example, body temperature) generated by a user's touch with the electronic device 1000 into electrical energy and may transmit the electrical energy to the internal battery 300. The energy conversion layer 400 may include a thermoelectric element which converts thermal energy into electrical energy.

The internal battery 300 may be charged on the basis of electrical energy.

The display layer 100, the internal battery 300, and the energy conversion layer 400 will be described in detail later.

The electro-optical module ELM may be an electronic component which transmits or receives a light signal. The electro-optical module ELM may transmit or receive a light signal through a partial region of the display module DM. In this embodiment, the electro-optical module ELM may include a camera module CAM and a sensor module SNM. The camera module CAM may include a camera. The sensor module SNM may include a sensor. For example, the sensor may include an infrared sensor.

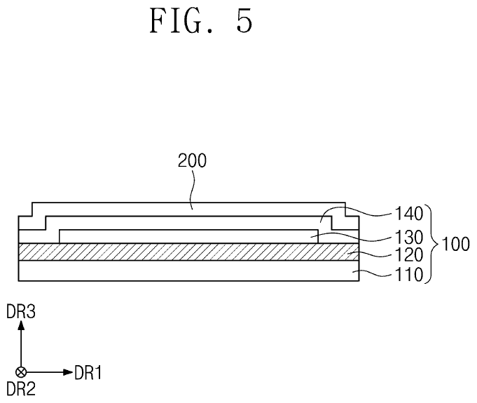

FIG. 5 is a schematic cross-sectional view of a display layer and a sensor layer according to an embodiment of the disclosure.

Referring to FIG. 5, the display layer 100 may include a base layer 110, a circuit layer 120, a light-emitting element layer 130, and an encapsulation layer 140.

The base layer 110 may be a member which provides a base surface on which the circuit layer 120 may be disposed. The base layer 110 may be a glass substrate, a metal substrate, or a polymer substrate. However, an embodiment of the disclosure is not limited thereto, and the base layer 110 may be an inorganic layer, an organic layer, or a composite material layer.

The base layer 110 may have a multi-layered structure. For example, the base layer 110 may include a first synthetic resin layer, a silicon oxide (SiOₓ) layer disposed on the first synthetic resin layer, an amorphous silicon (a-Si) layer disposed on the silicon oxide layer, and a second synthetic resin layer disposed on the amorphous silicon layer. The silicon oxide layer and the amorphous silicon layer may be referred to as a base barrier layer.

The first and second synthetic resin layers may each include a polyimide-based resin. Also, the first and second synthetic resin layers may each include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, or a perylene-based resin. In this specification, a “XYZ-based” resin may be considered as including a functional group of “XYZ”.

The circuit layer 120 may be disposed on the base layer 110. The circuit layer 120 may include an insulating layer, a semiconductor pattern, a conductive pattern, a signal line, and the like. An insulating layer, a semiconductor layer, and a conductive layer may be formed on the base layer 110 by a coating process, a deposition process, or the like, and then the insulating layer, the semiconductor layer, and the conductive layer may be selectively patterned by performing a photolithography process multiple times. The semiconductor pattern, the conductive pattern, and the signal line which may be included in the circuit layer 120 may be formed.

The light-emitting element layer 130 may be disposed on the circuit layer 120. The light-emitting element layer 130 may include a light-emitting element. For example, the light-emitting element layer 130 may include an organic light-emitting material, a quantum dot, a quantum rod, a micro-LED, or a nano-LED.

The encapsulation layer 140 may be disposed on the light-emitting element layer 130. The encapsulation layer 140 may protect the light-emitting element layer 130 from moisture, oxygen, and foreign material such as dust particles.

The display module DM (see FIG. 4) may further include a sensor layer 200. The sensor layer 200 may be formed on the display layer 100 through a continuous process. It may be described that the sensor layer 200 may be disposed (e.g., directly disposed) on the display layer 100. The wording, ‘being disposed directly’ means that a third component may not be disposed between the sensor layer 200 and the display layer 100. An additional adhesive member may not be disposed between the sensor layer 200 and the display layer 100. As another example, the sensor layer 200 and the display layer 100 may be coupled to each other through an adhesive member. The adhesive member may include a typical adhesive or bonding agent.

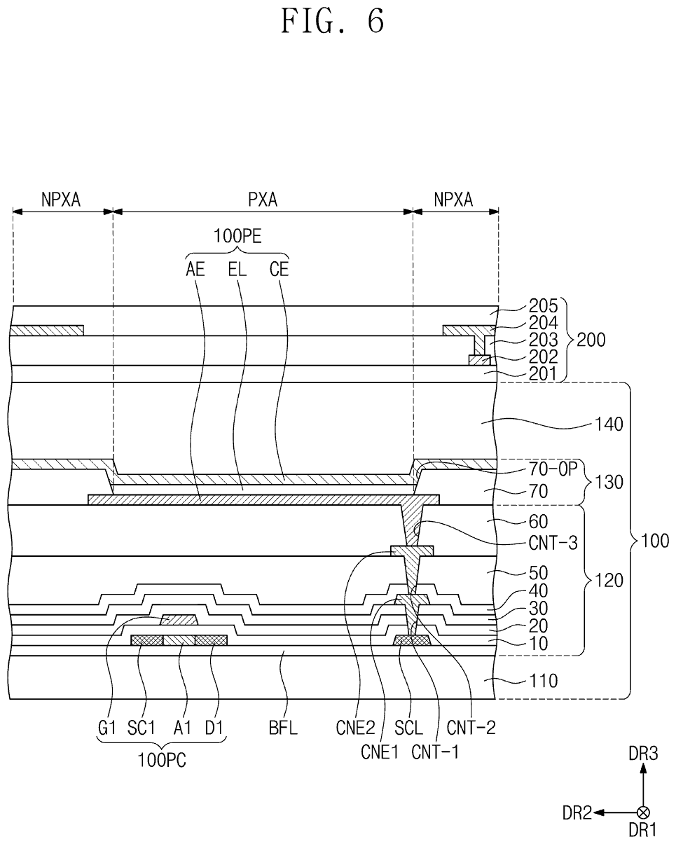

FIG. 6 is a schematic cross-sectional view of a display layer and a sensor layer according to an embodiment of the disclosure. In the description of FIG. 6, the same reference numerals or symbols may be used for the components described in FIG. 5, and a description thereof will be omitted.

Referring to FIG. 6, at least one inorganic layer may be formed on a top surface of the base layer 110. The inorganic layer may include at least one of aluminum oxide, titanium oxide, silicon oxide, silicon oxynitride, zirconium oxide, or hafnium oxide. The inorganic layer may be formed as multiple layers. The multi-layered inorganic layers may constitute a barrier layer and/or a buffer layer. In this embodiment, the display layer 100 is illustrated as including a buffer layer BFL.

The buffer layer BFL may improve bonding force between the base layer 110 and the semiconductor pattern. The buffer layer BFL may include a silicon oxide layer and a silicon nitride layer, and the silicon oxide layer and the silicon nitride layer may be alternately stacked on each other.

The semiconductor pattern may be disposed on the buffer layer BFL. The semiconductor pattern may include polysilicon. However, an embodiment of the disclosure is not limited thereto, and the semiconductor pattern may include amorphous silicon, low-temperature polycrystalline silicon, or an oxide semiconductor.

FIG. 6 merely illustrates a part of the semiconductor pattern, and the semiconductor pattern may be further disposed in another region. The semiconductor pattern may be arranged across pixels in accordance with a specific rule. Electrical properties of the semiconductor pattern may vary depending on whether the semiconductor pattern may be doped or not. The semiconductor pattern may have a first region which has a high conductivity and a second region which has a low conductivity. The first region may be doped with an N-type dopant or a P-type dopant. A P-type transistor may include a doped region which may be doped with a P-type dopant, and an N-type transistor may include a doped region which may be doped with an N-type dopant. The second region may be an undoped region or may be doped at a lower concentration than the first region.

The conductivity of the first region may be greater than that of the second region, and the first region may substantially serve as an electrode or a signal line. The second region may substantially correspond to an active (or a channel) region of a transistor. In other words, a part of the semiconductor pattern may be a transistor's active region (or active layer), another part may be a transistor's source region or drain region, and still another part may be a connection electrode or a connection signal line.

Pixels may each have an equivalent circuit including seven transistors, one capacitor, and a light-emitting element, and the equivalent circuit of a pixel may be deformed into various forms. FIG. 6 illustrates as an example one transistor 100PC and a light-emitting element 100PE which may be included in the pixel.

The transistor 100 PC may include a source region SC1, an active region A1, a drain region D1, and a gate G1. The source region SC1, the active region A1, and the drain D1 region may be formed from the semiconductor pattern. The source region SC1 and the drain region D1 may respectively extend from the active region A1 in opposite directions in a schematic cross-sectional view. FIG. 6 illustrates a part of a connection signal line SCL formed from the semiconductor pattern. Although not illustrated separately, the connection signal line SCL may be electrically connected to the drain region D1 of the transistor 100PC in a plan view.

A first insulating layer 10 may be disposed on the buffer layer BFL. The first insulating layer 10 may overlap multiple pixels in common, and may cover the semiconductor pattern. The first insulating layer 10 may be an inorganic layer and/or an organic layer, and may have a single-or multi-layered structure. The first insulating layer 10 may include at least one of aluminum oxide, titanium oxide, silicon oxide, silicon nitride, silicon oxynitride, zirconium oxide, or hafnium oxide. In this embodiment, the first insulating layer 10 may be a single-layered silicon oxide layer. An insulating layer of the circuit layer 120, to be described later, as well as the first insulating layer 10 may be an inorganic layer and/or an organic layer, and may have a single-or multi-layered structure. The inorganic layer may include at least one of the aforementioned materials, but an embodiment of the disclosure is not limited thereto.

The gate G1 may be disposed on the first insulating layer 10. The gate G1 may be a part of a metal pattern. The gate G1 overlaps the active region A1. The gate G1 may function as a mask in a process of doping the semiconductor pattern.

A second insulating layer 20 may be disposed on the first insulating layer 10, and may cover the gate G1. The second insulating layer 20 may overlap the pixels in common. The second insulating layer 20 may be an inorganic layer and/or an organic layer, and may have a single-or multi-layered structure. The second insulating layer 20 may include at least one of silicon oxide, silicon nitride, or silicon oxynitride. In this embodiment, the second insulating layer 20 may have a multi-layered structure including a silicon oxide layer and a silicon nitride layer.

A third insulating layer 30 may be disposed on the second insulating layer 20. The third insulating layer 30 may have a single-or multi-layered structure. For example, the third insulating layer 30 may have a multi-layered structure including a silicon oxide layer and a silicon nitride layer.

A first connection electrode CNE1 may be disposed on the third insulating layer 30. The first connection electrode CNE1 may be electrically connected to the connection signal line SCL through a contact hole CNT-1 which passes through the first, second, and third insulating layers 10, 20, and 30.

A fourth insulating layer 40 may be disposed on the third insulating layer 30. The fourth insulating layer 40 may be a single-layered silicon oxide layer. A fifth insulating layer 50 may be disposed on the fourth insulating layer 40. The fifth insulating layer 50 may be an organic layer.

A second connection electrode CNE2 may be disposed on the fifth insulating layer 50. The second connection electrode CNE2 may be electrically connected to the first connection electrode CNE1 through a contact hole CNT-2 which passes through the fourth insulating layer 40 and the fifth insulating layer 50.

A sixth insulating layer 60 may be disposed on the fifth insulating layer 50, and may cover the second connection electrode CNE2. The sixth insulating layer 60 may be an organic layer.

The light-emitting element layer 130 may be disposed on the circuit layer 120. The light-emitting element layer 130 may include the light-emitting element 100PE. For example, the light-emitting element layer 130 may include an organic light-emitting material, a quantum dot, a quantum rod, a micro-LED, or a nano-LED. Hereinafter, the light-emitting element 100PE may be exemplarily illustrated as an organic light-emitting element, but an embodiment of the disclosure is not particularly limited thereto.

The light-emitting element 100PE may include a first electrode AE, a light-emitting layer EL, and a second electrode CE. The first electrode AE may be disposed on the sixth insulating layer 60. The first electrode AE may be electrically connected to the second connection electrode CNE2 through a contact hole CNT-3 which passes through the sixth insulating layer 60.

A pixel defining film 70 may be disposed on the sixth insulating layer 60, and may cover a portion of the first electrode AE. An opening 70-OP may be defined in the pixel defining film 70. The opening 70-OP of the pixel defining film 70 exposes at least a portion of the first electrode AE.

The first active region F-AA (see FIG. 1A) and the second active region R-AA (see FIG. 1C) may include a light-emitting region PXA and a non-light-emitting region NPXA adjacent to the light-emitting region PXA. The non-light-emitting region NPXA may surround the light-emitting region PXA. In this embodiment, the light-emitting region PXA may be defined to correspond to a partial region of the first electrode AE which may be exposed by the opening 70-OP.

The light-emitting layer EL may be disposed on the first electrode AE. The light-emitting layer EL may be disposed in a region corresponding to the opening 70-OP. The light-emitting layer EL may be formed separately in each pixel. In case that the light-emitting layers EL may be formed separately in pixels, respectively, each of the light-emitting layers EL may emit light of at least one color among blue, red, and green. However, an embodiment of the disclosure is not limited thereto, and the light-emitting layer EL may be electrically connected to pixels and provided in common. The light-emitting layer EL may provide blue light or white light.

The second electrode CE may be disposed on the light-emitting layer EL. The second electrode CE may have an integrated shape, and may be disposed in multiple pixels in common.

Although not illustrated, a hole control layer may be disposed between the first electrode AE and the light-emitting layer EL. The hole control layer may be disposed in the light-emitting region PXA and the non-light-emitting region NPXA in common. The hole control layer may include a hole transport layer, and may further include a hole injection layer. An electron control layer may be disposed between the light-emitting layer EL and the second electrode CE. The electron control layer may include an electron transport layer, and may further include an electron injection layer. The hole control layer and the electron control layer may be formed in the pixels in common using an open mask.

The encapsulation layer 140 may be disposed on the light-emitting element layer 130. The encapsulation 140 may include an inorganic layer, an organic layer, and an inorganic layer which may be sequentially stacked on each other, but layers constituting the encapsulation layer 140 are not limited thereto.

The inorganic layers may protect the light-emitting element layer 130 from moisture and oxygen, and the organic layer may protect the light-emitting element layer 130 from foreign material such as dust particles. The inorganic layers may include a silicon nitride layer, a silicon oxynitride layer, a silicon oxide layer, a titanium oxide layer, an aluminum oxide layer, or the like. The organic layer may include an acrylate-based organic layer, but an embodiment of the disclosure is not limited thereto.

The sensor layer 200 may be formed on the display layer 100 through a continuous process. It may be described that the sensor layer 200 may be disposed (e.g., directly disposed) on the display layer 100. The wording, ‘being disposed directly’ means that a third component may not be disposed between the sensor layer 200 and the display layer 100. An additional adhesive member may not be disposed between the sensor layer 200 and the display layer 100. As another example, the sensor layer 200 may be coupled to the display layer 100 through an adhesive member. The adhesive member may include a typical adhesive or bonding agent.

The sensor layer 200 may include a base insulating layer 201, a first conductive layer 202, a sensing insulating layer 203, a second conductive layer 204, and a cover insulating layer 205.

The base insulating layer 201 may be an inorganic layer including at least any one of silicon nitride, silicon oxynitride, or silicon oxide. As another example, the base insulating layer 201 may be an organic layer including an epoxy resin, an acrylic resin, an imide-based resin, or a combination thereof. The base insulating layer 201 may have a single-layered structure, or a multi-layered structure in which layers may be stacked on each other in the third direction DR3.

The first conductive layer 202 and the second conductive layer 204 may each have a single-layered structure, or a multi-layered structure in which layers may be stacked on each other in the third direction DR3.

A conductive layer having a single-layered structure may include a metal layer or a transparent conductive layer. The metal layer may include molybdenum, silver, titanium, copper, aluminum, or an alloy thereof. The transparent conductive layer may include a transparent conductive oxide such as an indium tin oxide (ITO), an indium zinc oxide (IZO), a zinc oxide (ZnO), an indium zinc tin oxide (IZTO), the like, or a combination thereof. The transparent conductive layer may include a conductive polymer such as PEDOT, a metal nanowire, graphene, the like, or a combination thereof.

A conductive layer having a multi-layered structure may include metal layers. The metal layers may have, for example, a three-layer structure of titanium/aluminum/titanium. The conductive layer having a multi-layered structure may include at least one metal layer and at least one transparent conductive layer.

At least one of the sensing insulating layer 203 or the cover insulating layer 205 may include an inorganic film. The inorganic film may include at least one of aluminum oxide, titanium oxide, silicon oxide, silicon nitride, silicon oxynitride, zirconium oxide, or hafnium oxide.

At least one of the sensing insulating layer 203 or the cover insulating layer 205 may include an organic film. The organic film may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyimide-based resin, a polyamide-based resin, or a perylene-based resin.

FIG. 7 is a schematic cross-sectional view of the electronic device taken along line I-I′ of FIG. 1A according to an embodiment of the disclosure.

Referring to FIGS. 1B and 7, a first non-folding display region NFA1-D, a folding display region FA1-D, and a second non-folding display region NFA2-D may be defined in the display layer 100. The folding display region FA1-D may be folded with respect to the first folding axis FX1 described above. When viewed on a plane (or in a plan view), the first non-folding display region NFA1-D may overlap at least a portion of the first non-folding region NFA1, the folding display region FA1-D may overlap the folding region FA1, and the second non-folding display region NFA2-D may overlap at least a portion of the second non-folding region NFA2.

The electronic device 1000 may include a window WM, an impact-absorbing layer SAL, a sensor layer 200, a display layer 100, a flexible printed circuit board FPCB, a panel protection layer PPL, a barrier layer BRL, a support plate FP, a protective layer TPU, a metal layer CU, a heat dissipation layer SHL, an insulating layer ISL, an internal battery 300, an energy conversion layer 400, a driving chip 500, a processor 600, and first to tenth adhesive layers AL1 to AL10.

The window WM may include a hard coating layer HC, a window protection layer WP, a printing layer PIT, and a window layer WIN.

The window layer WIN may protect the display layer 100 from external scratches. The window layer WIN may have an optically transparent property. The window layer WIN may include glass. However, an embodiment of the disclosure is not limited thereto, and the window layer WIN may include a synthetic resin film.

The window layer WIN may have a single or a multi-layered structure. For example, the window layer WIN may include multiple synthetic resin films which may be coupled by an adhesive, or may include a glass substrate and a synthetic resin film which may be coupled by an adhesive.

The window protection layer WP may be disposed on the window layer WIN. The window protection layer WP may include a flexible plastic material such as polyimide or polyethylene terephthalate. The hard coating layer HC may be disposed on a top surface of the window protection layer WP.

The printing layer PIT may be disposed on a bottom surface of the window protection layer WP. The printing layer PIT may have a black color, but the color of the printing layer PIT is not limited thereto. The printing layer PIT may be adjacent to an edge of the window protection layer WP.

A first adhesive layer AL1 may be disposed between the window protection layer WP and the window layer WIN. The window protection layer WP and the window layer WIN may be bonded to each other by the first adhesive layer AL1. The first adhesive layer AL1 may cover the printing layer PIT.

The impact-absorbing layer SAL may be disposed on the sensor layer 200. The impact-absorbing layer SAL may protect the sensor layer 200 by absorbing external impact applied toward the sensor layer 200 from above the electronic device 1000. The impact-absorbing layer SAL may be manufactured in the form of a stretched film.

The impact-absorbing layer SAL may include a flexible plastic material. The flexible plastic material may be defined as a synthetic resin film. For example, the impact-absorbing layer SAL may include a flexible plastic material such as polyimide (PI) or polyethylene terephthalate (PET).

A second adhesive layer AL2 may be disposed between the window layer WIN and the impact-absorbing layer SAL. The window layer WIN and the impact-absorbing layer SAL may be bonded to each other by the second adhesive layer AL2.

The sensor layer 200 may be disposed under the impact-absorbing layer SAL. The sensor layer 200 may include a flexible material.

A third adhesive layer AL3 may be disposed between the impact-absorbing layer SAL and the sensor layer 200. The impact-absorbing layer SAL and the sensor layer 200 may be bonded to each other by the third adhesive layer AL3.

The display layer 100 may be disposed under the sensor layer 200. The display layer 100 may include a flexible material. The display layer 100 may extend in an opposite direction of the first direction DR1, and may be electrically connected to the flexible printed circuit board FPCB via the extended part.

The flexible printed circuit board FPCB may include a first portion FPCB1, a bending portion FPCBB, and a second portion FPCB2. The bending portion FPCBB may be a portion extending from the first portion FPCB1, and the second portion FPCB2 may be a portion extending from the bending portion FPCBB.

The first portion FPCB1 may contact the display layer 100, the bending portion FPCBB may be bent to a rear surface of the display layer 100, and the second portion FPCB2 may be electrically connected to the driving chip 500 and the driving chip 500 may be mounted thereon.

The panel protection layer PPL may protect a lower part of the display layer 100. The panel protection layer PPL may include a flexible plastic material. For example, the panel protection layer PPL may include polyethylene terephthalate (PET).

A fourth adhesive layer AL4 may be disposed between the display layer 100 and the panel protection layer PPL. The display layer 100 and the panel protection layer PPL may be bonded to each other by the fourth adhesive layer AL4.

The barrier layer BRL may be disposed under the panel protection layer PPL. The barrier layer BRL may increase resistance to compressive force due to external pressing. Accordingly, the barrier layer BRL may serve to prevent deformation of the display layer 100. The barrier layer BRL may include a flexible plastic material such as polyimide or polyethylene terephthalate.

The barrier layer BRL may have a light-absorbing color. For example, the barrier layer BRL may have a black color. When the display layer 100 is viewed from above the display layer 100, components disposed under the barrier layer BRL may not be viewed.

A fifth adhesive layer AL5 may be disposed between the panel protection layer PPL and the barrier layer BRL. The panel protection layer PPL and the barrier layer BRL may be bonded to each other by the fifth adhesive layer AL5.

A sixth adhesive layer AL6 may be disposed between the barrier layer BRL and the support plate FP. The barrier layer BRL and the support plate FP may be bonded to each other by the sixth adhesive layer AL6.

The sixth adhesive layer AL6 may overlap the first and second non-folding display regions NFA1-D and NFA2-D in a plan view and may not overlap the folding display region FA1-D. The sixth adhesive layer AL6 may not be disposed in the folding display region FA1-D.

The support plate FP may be disposed under the barrier layer BRL. The support plate FP may have higher rigidity than the display layer 100 and the sensor layer 200, and may be disposed under the display layer 100 and the sensor layer 200 to support the display layer 100 and the sensor layer 200.

The support plate FP may have a continuously integrated shape. The support plate FP may be disposed under the display layer 100 to support the display layer 100. The support plate FP may include a metal material and/or a nonmetal material.

In a plan view, multiple openings OP may be defined in a portion of the support plate FP overlapping the folding display region FA1-D. In a plan view, the openings OP may overlap the folding display region FA1-D. The openings OP may be disposed to be spaced apart in the first direction DR1, and may be disposed to pass through the support plate FP in the third direction DR3. The openings OP may be formed by a laser process or a microblast process.

Since the openings OP are defined in a portion of the support plate FP overlapping the folding display region FA1-D, the flexibility of the portion of the support plate FP overlapping the folding display region FA1-D may be improved. Accordingly, the support plate FP may be readily folded about the folding display region FA1-D.

The support plate FP may include a folding portion FA-FP, a first non-folding portion NFA1-FP, and a second non-folding portion NFA2-FP. A portion of the support plate FP corresponding to the openings OP may be defined as the folding portion FA-FP. The folding portion FA-FP may be folded with respect to the first folding axis FX1 (see FIG. 1B) extending in the second direction DR2 intersecting the first direction DR1.

Portions of the support plate FP absent the openings OP may be defined as the first non-folding portion NFA1-FP or the second non-folding portion NFA2-FP. Portions of the support plate FP which is in the first direction DR1 from the folding portion FA-FP may be referred to as the first non-folding portion NFA1-FP, and portions of the support plate FP which is spaced apart from the first non-folding portion NFA1-FP by the folding portion FA-FP may be referred to as the second non-folding portion NFA2-FP.

The protective layer TPU may be disposed under the support plate FP. In a plan view, the protective layer TPU may overlap the folding portion FA-FP. The protective layer TPU may prevent foreign material from entering the openings OP in the folding portion FA-FP. The protective layer TPU may include thermoplastic polyurethane. However, an embodiment of the disclosure is not limited thereto.

A seventh adhesive layer AL7 may be disposed between the support plate FP and the protective layer TPU. The support plate FP and the protective layer TPU may be bonded to each other by the seventh adhesive layer AL7.

The metal layer CU may be disposed under the protective layer TPU. The metal layer CU may prevent the folding portion FA-FP from being deformed by heat. The metal layer CU may include molybdenum, silver, titanium, copper, aluminum, an alloy thereof, or a combination thereof. The metal layer CU may be divided into two parts under the folding portion FA-FP. In a plan view, the metal layer CU may not overlap at least a portion of the folding portion FA-FP.

An eighth adhesive layer AL8 may be disposed between the protective layer TPU and the metal layer CU. The protective layer TPU and the metal layer CU may be bonded to each other by the eighth adhesive layer AL8.

The eighth adhesive layer AL8 may overlap the first and second non-folding display regions NFA1-D and NFA2-D in a plan view and may not overlap at least a portion of the folding display region FA1-D.

The heat dissipation layer SHL may be disposed under the metal layer CU. The heat dissipation layer SHL may include at least any one of graphite, copper (Cu), or aluminum (Al) which has a good heat dissipation property, but an embodiment of the disclosure is not limited thereto. The heat dissipation layer SHL may not only improve a heat dissipation property but also have an electromagnetic shielding property or an electromagnetic absorbing property. The heat dissipation layer SHL may be divided into two parts under the folding portion FA-FP. In a plan view, the heat dissipation layer SHL may not overlap at least a portion of the folding portion FA-FP.

A ninth adhesive layer AL9 may be disposed between the metal layer CU and the heat dissipation layer SHL. The metal layer CU and the heat dissipation layer SHL may be bonded to each other by the ninth adhesive layer AL9.

The ninth adhesive layer AL9 may overlap the first and second non-folding display regions NFA1-D and NFA2-D in a plan view and may not overlap at least a portion of the folding display region FA1-D.

The insulating layer ISL may be disposed under the heat dissipation layer SHL and may be disposed on the internal battery 300. The insulating layer ISL may prevent short-circuiting between the heat dissipation layer SHL and the internal battery 300. The insulating layer ISL may include an electrical insulating tape. The electrical insulating tape may include a synthetic resin layer and an adhesive layer which have high electrical insulating properties. The insulating layer ISL may be divided into two parts under the folding portion FA-FP. In a plan view, the insulating layer ISL may not overlap at least a portion of the folding portion FA-FP.

A tenth adhesive layer AL10 may be disposed between the heat dissipation layer SHL and the insulating layer ISL. The heat dissipation layer SHL and the insulating layer ISL may be bonded to each other by the tenth adhesive layer AL10.

The tenth adhesive layer AL10 may overlap the first and second non-folding display regions NFA1-D and NFA2-D in a plan view and may not overlap at least a portion of the folding display region FA1-D.

The first to tenth adhesive layers AL1 to AL10 may each include a transparent adhesive such as a pressure sensitive adhesive (PSA) or an optically clear adhesive (OCA), but a type of an adhesive is not limited thereto.

The internal battery 300 may be disposed under the insulating layer ISL. In a plan view, the internal battery 300 may overlap at least a portion of the second non-folding portion NFA2-FP. FIG. 7 illustrates that the internal battery 300 overlaps only the second non-folding portion NFA2-FP. However in a plan view, the internal battery 300 may overlap at least a portion of each of the first non-folding portion NFA1-FP and the second non-folding portion NFA2-FP.

The internal battery 300 may store electrical energy. The internal battery 300 may provide the stored electrical energy to the driving chip 500.

The internal battery 300 may be a lithium-ion battery. The lithium-ion battery may have a thickness of about 500 μm or less. The internal battery 300 may be a thin battery.

As another example, the internal battery 300 may be a stretchable battery. The stretchable battery may be composed of organogel. In case that the material of the internal battery 300 includes organogel, the adhesiveness of the internal battery 300 may be improved by irradiating the organogel with an electron beam (E-beam). The internal battery 300 may be used as an adhesive by irradiating the internal battery 300 with the electron beam (E-beam) to impart adhesiveness to the internal battery 300, and thus a lower structure of the internal battery 300 may be attached. An additional adhesive layer may not be required. However, an embodiment of the disclosure is not limited thereto.

According to the disclosure, the internal battery 300 may be additionally provided in the display module DM (see FIG. 4) in addition to an existing battery unit which may be provided in the power supply module PSM (see FIG. 4) for supplying power. The internal battery 300 may provide a voltage to drive the display layer 100, and thus a size and a thickness of the battery unit in the power supply module PSM (see FIG. 4) may be reduced. Accordingly, an available space in a lower structure of the electronic device 1000 may be secured. A thickness of the electronic device 1000 may be reduced because of securing the space. Thus, the slim electronic device 1000 may be provided.

According to the disclosure, the internal battery 300, which may be integrally built in the display module DM of the electronic device 1000, may function as auxiliary power supply by providing power in case of an emergency. For example, in case that a battery unit in the power supply module PSM (see FIG. 4), which may be a main battery of the electronic device 1000, is discharged, the electronic device 1000 may be operated by using the internal battery 300 built in the display module DM (see FIG. 4) in an emergency. Accordingly, the electronic device 1000 with improved reliability may be provided.

The energy conversion layer 400 may be disposed under the internal battery 300. The internal battery 300 and the energy conversion layer 400 may be bonded to each other by an adhesive layer (not illustrated). In a plan view, the energy conversion layer 400 may overlap at least a portion of the second non-folding portion NFA2-FP. FIG. 7 illustrates that the energy conversion layer 400 overlaps only the second non-folding portion NFA2-FP, but in a plan view the energy conversion layer 400 may overlap at least a portion of each of the first non-folding portion NFA1-FP and the second non-folding portion NFA2-FP in accordance with the arrangement conditions of the internal battery 300.

The energy conversion layer 400 may convert heat HT generated by the processor 600 or heat generated by a user's touch with the electronic device 1000 into electrical energy. The energy conversion layer 400 may transmit the electrical energy to the internal battery 300.

The energy conversion layer 400 may be a thermoelectric element. The thermoelectric element may operate at room temperature. The thermoelectric element may be composed of at least one compound of a bismuth-telluride (Bi—Te)-based compound, a hybrid compound including bismuth-telluride (Bi—Te)-based, a silicon-based compound, or a zinc-antimony (Zn—Sb)-based compound.

The driving chip 500 may be disposed under the energy conversion layer 400. The energy conversion layer 400 and a portion of the second portion FPCB2 may be bonded to each other by an adhesive layer (not illustrated). In a plan view, the driving chip 500 may overlap at least a portion of the second non-folding portion NFA2-FP. FIG. 7 illustrates that the driving chip 500 overlaps only the second non-folding portion NFA2-FP, but in a plan view the driving chip 500 may overlap at least a portion of each of the first non-folding portion NFA1-FP and the second non-folding portion NFA2-FP.

Electrical energy may be provided to the driving chip 500 from the internal battery 300. The driving chip 500 may be electrically connected to the display layer 100 via the flexible printed circuit board FPCB and may provide a driving voltage to the display layer 100.

The processor 600 may be disposed under the driving chip 500. The driving chip 500 and the processor 600 may be bonded to each other by an adhesive layer (not illustrated). In a plan view, the processor 600 may overlap at least a portion of the second non-folding portion NFA2-FP. FIG. 7 illustrates that the processor 600 overlaps only the second non-folding portion NFA2-FP, but in a plan view the processor 600 may overlap at least a portion of each of the first non-folding portion NFA1-FP and the second non-folding portion NFA2-FP.

The processor 600 may control an overall operation of the electronic device 1000. The processor 600 may generate heat HT while performing a control operation.

The heat HT generated by the processor 600 may be transferred to the energy conversion layer 400 through the driving chip 500 and the second portion FPCB2 of the flexible printed circuit board FPCB. The energy conversion layer 400 may convert the heat HT into electrical energy. The electrical energy may be stored in the internal battery 300. The electrical energy stored in the internal battery 300 may be transferred to the driving chip 500. The driving chip 500 may receive the electrical energy and provide a driving voltage to the display layer 100.

According to the disclosure, the heat HT generated during the driving of the processor 600 or heat generated by a user's touch with the electronic device 1000 may be converted into electrical energy and the electrical energy may be used to drive the display layer 100 so that power may be supplied autonomously in the display module DM (see FIG. 4). Accordingly, power consumption required to operate the electronic device 1000 may be reduced. In case that the required power consumption is reduced, the size of the battery unit in the power supply module PSM (see FIG. 4) which may be a main battery may be reduced. Thus, an available space in the lower structure of the electronic device 1000 may be secured.

According to the description above, an electronic device may autonomously generate and consume power in a display module. The generated power may be consumed by driving a display layer. Accordingly, power consumption required to operate the electronic device may be reduced.

In the above, description has been made with reference to embodiments of the disclosure, but those skilled in the art or those of ordinary skill in the relevant technical field may understand that various modifications and changes may be made to the disclosure within the scope not departing from the spirit and the technology scope of the disclosure described in the claims to be described later. Therefore, the technical scope of the disclosure is not limited to the contents described in the detailed description of the specification, but should be determined by the claims.

What is claimed is:

1. An electronic device comprising:
a display layer comprising a first non-folding display region, a second non-folding display region spaced apart from the first non-folding display region in a first direction, and a folding display region disposed between the first non-folding display region and the second non-folding display region;
a support plate disposed under the display layer, the support plate comprising a folding portion folded with respect to a folding axis extending in a second direction intersecting the first direction, a first non-folding portion extending in the first direction from the folding portion, and a second non-folding portion spaced apart from the first non-folding portion by the folding portion;
an internal battery disposed under the support plate;
an energy conversion layer disposed under the internal battery and electrically connected to the internal battery;
a driving chip disposed under the energy conversion layer and electrically connected to the internal battery and the display layer; and
a processor disposed under the driving chip and configured to drive the driving chip.

2. The electronic device of claim 1, wherein the internal battery overlaps at least a portion of the second non-folding portion in a plan view.

3. The electronic device of claim 1, wherein the energy conversion layer overlaps at least a portion of the second non-folding portion in a plan view.

4. The electronic device of claim 1, wherein the driving chip overlaps at least a portion of the second non-folding portion in a plan view.

5. The electronic device of claim 1, wherein the processor overlaps at least a portion of the second non-folding portion in a plan view.

6. The electronic device of claim 1, wherein
the driving chip is electrically connected to the display layer via a flexible printed circuit board,
the flexible printed circuit board comprises a first portion, a bending portion extending from the first portion, and a second portion extending from the bending portion,
the first portion contacts the display layer,
the bending portion is bent to a rear surface of the display layer, and
the driving chip is mounted on the second portion.

7. The electronic device of claim 1, wherein the energy conversion layer converts heat generated by the processor into electrical energy.

8. The electronic device of claim 7, wherein the internal battery stores the electrical energy and provides the electrical energy to the driving chip.

9. The electronic device of claim 8, wherein the driving chip is supplied with the electrical energy and provides a driving voltage to the display layer.

10. The electronic device of claim 1, wherein the energy conversion layer comprises a material which operates at room temperature.

11. The electronic device of claim 1, wherein
a plurality of openings are disposed in the folding portion, and
the plurality of openings are spaced apart in the first direction.

12. The electronic device of claim 1, further comprising:
a protective layer, a metal layer, a heat dissipation layer, and an insulating layer,
wherein the protective layer, the metal layer, the heat dissipation layer, and the insulating layer are disposed between the support plate and the internal battery.

13. The electronic device of claim 12, wherein
the protective layer is disposed under the support plate, and
the protective layer overlaps the folding portion in a plan view.

14. The electronic device of claim 12, wherein
the metal layer is disposed under the protective layer, and
the metal layer does not overlap at least a portion of the folding portion in a plan view.

15. The electronic device of claim 12, wherein
the heat dissipation layer is disposed under the metal layer, and
the heat dissipation layer does not overlap at least a portion of the folding portion in a plan view.

16. The electronic device of claim 12, wherein
the insulating layer is disposed under the heat dissipation layer and is disposed on the internal battery, and
the insulating layer does not overlap at least a portion of the folding portion in a plan view.

17. An electronic device comprising:
a display layer;
a support plate disposed under the display layer;
an internal battery disposed under the support plate;
an energy conversion layer disposed under the internal battery and electrically connected to the internal battery;
a driving chip disposed under the energy conversion layer and electrically connected to the internal battery and the display layer;
a processor disposed under the driving chip and configured to drive the driving chip; and
a flexible printed circuit board electrically connecting the driving chip to the display layer, wherein
the flexible printed circuit board comprises a first portion, a bending portion extending from the first portion, and a second portion extending from the bending portion,
the first portion contacts the display layer,
the bending portion is bent to a rear surface of the display layer, and
the driving chip is mounted on the second portion.

18. The electronic device of claim 17, wherein the energy conversion layer converts heat generated by the processor into electrical energy.

19. The electronic device of claim 18, wherein the internal battery stores the electrical energy and provides the electrical energy to the driving chip.

20. The electronic device of claim 19, wherein the driving chip is supplied with the electrical energy and provides a driving voltage to the display layer.
